(19) United States
(12) Patent Application Publication
(10) Pub. No.: US 2026/0296803 A1
(43) Pub. Date: Oct. 1, 2026

(54) WET BENCH SYSTEM AND METHOD FOR GRABBING BATCH OF WAFERS IN PROCESSING SOLUTION

(71) Applicants: TSMC CHINA COMPANY LIMITED, Shanghai (CN); TAIWAN SEMICONDUCTOR MANUFACTURING COMPANY, LTD., Hsinchu (TW)

(72) Inventors: Qiang SU, Shanghai City (CN); Eason XU, Shanghai City (CN); Chuang LI, Shanghai City (CN); J.Y. ZHANG, Shanghai City (CN)

(73) Assignees: TSMC CHINA COMPANY LIMITED, Shanghai (CN); TAIWAN SEMICONDUCTOR MANUFACTURING COMPANY, LTD., Hsinchu (TW)

(21) Appl. No.: 19/179,085

(22) Filed: Apr. 15, 2025

(30) Foreign Application Priority Data
Mar. 26, 2025 (CN) 202520554660.8

(51) Int. Cl. B65G 47/90; H10P 72/76

(52) U.S. Cl. CPC B65G 47/905; H10P 72/7602; B65G 2201/0214

(57) ABSTRACT

A method includes grabbing a gripping assembly and moving the gripping assembly into a processing solution. The batch of wafers in the processing solution is clamped by using the gripping assembly. The gripping assembly is locked. The gripping assembly with the batch of wafers is pulled out of the processing solution.

### PRIORITY CLAIM AND CROSS-REFERENCE

The present application claims priority to China Application Serial Number 202520554660.8, filed Mar. 26, 2025, which is herein incorporated by reference.

### BACKGROUND

Etching is used in microfabrication to chemically remove layers from the surface of a wafer during manufacturing. Etching is a process module, and every wafer undergoes many etching operations before it is complete. For many etch operations, part of the wafer is protected from the etchant by a “masking” material which resists etching. In some cases, the masking material is a photoresist which has been patterned using photolithography. Other situations require a more durable mask, such as silicon nitride.

The wafer can be immersed in a bath of etchant, which can be agitated to achieve good process control. For instance, buffered hydrofluoric acid (BHF) is used commonly to etch silicon dioxide over a silicon substrate. Different specialized etchants can be used to characterize the surface etched.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic block diagram of a wet bench system in accordance with some embodiments of the present disclosure.

FIG. 2 is a flowchart illustrating a method for processing a batch of wafers in the wet bench system in accordance with some embodiments.

FIGS. 3A-3L are partial views of the wet bench system during various stages of processing the batch of wafers according to the method.

FIG. 4 is a schematic view of a batch of wafers disposed in the batch wafer carrier according to some embodiments.

FIG. 5A is a perspective view of the gripping assembly in an unlatched state in accordance with some embodiments of the present disclosure.

FIG. 5B is a front view of the gripping assembly in FIG. 5A.

FIG. 5C is a side view of the gripping assembly in FIG. 5A.

FIG. 6 is a perspective view of a trolley and a wafer container in accordance with some embodiments of the present disclosure.

FIGS. 7A-7F are partial views of the trolley during various stages of loading the wafers in a wafer container according to the operation S26 in FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

Some embodiments of the present disclosure are related to wet etching processes in wafer fabrication processes. More specifically, some embodiments of the present disclosure are related to provide manual grabbing a batch of wafers immersed in a wet tank/chamber to prevent the wafer over-immersed in the etchant or cleaning liquid when a machine conveying system supposed to grab or move the wafers is not functioning.

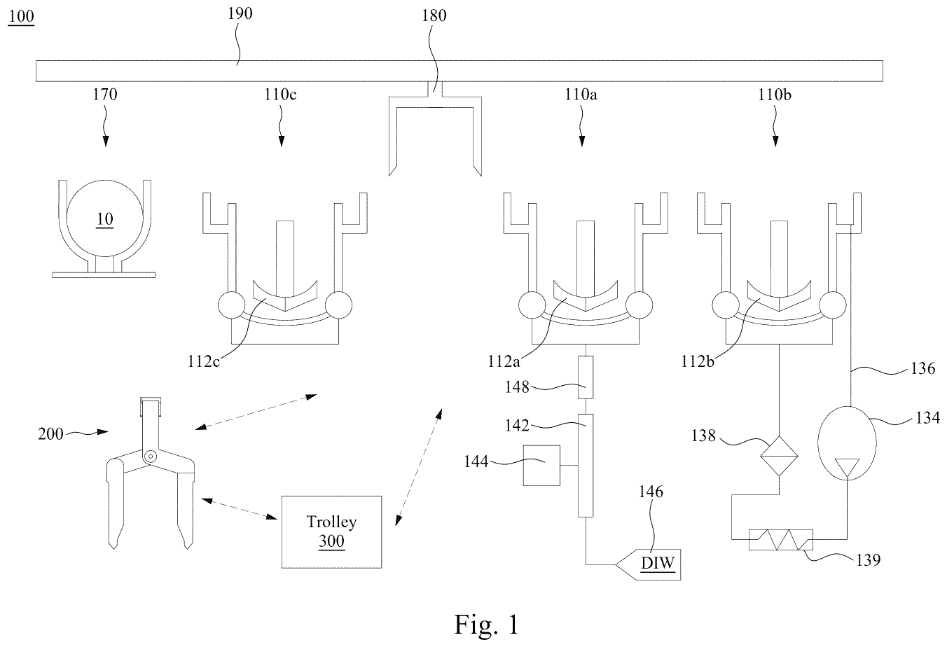

FIG. 1 is a schematic block diagram of a wet bench system 100 in accordance with some embodiments of the present disclosure. The wet bench system 100 may include one or more processing apparatus(es) 110a and 110b. In some embodiments, the processing apparatus(es) 110a and 110b may be arranged in pairs and each pair as a tank set. As shown in FIG. 1, one tank set is shown. Any numbers of tank sets may be included in the wet bench system 100 as desired for various applications and operations. The processing apparatus 110b in each tank set may be configured to retain a processing solution, e.g., etchant. During wet processes, a batch of wafers 10 are immersed in the processing solution. The processing solution used to achieve a target wet process, such as wet etching. The processing solution in the processing apparatus 110b may be circulated and used by many batches of wafers 10. The processing apparatus 110a in each tank set is configured to retain a cleaning liquid such as a diluted processing solution, a rinse solution, and/or deionized water. One or more chemical source may be connected to the processing apparatus 110a to selectively provide one or more processing solutions to the processing apparatus 110a. After being processed in the processing apparatus 110b, a batch of wafers 10 are then dipped into the processing apparatus 110a in the corresponding to be rinsed off and/or cleaned. The processing apparatus 110a provides a fresh solution for each batch of wafers 10.

In some embodiments, the wet bench system 100 may also include a processing apparatus (or so called a dryer) 110c. The processing apparatus 110c may be configured to dry the wafers 10 after processing in the processing apparatus 110a and 110b by spinning or using isopropyl alcohol (IPA). In some embodiments, the processing apparatus 110c is a low pressure dryer, such as a dryer operates by the Marangoni drying effect using IPA (isopropyl alcohol).

The wet bench system 100 may further include a loading station 170 and a wafer transfer robot 180. At the loading station 170, wafers 10 to be processed may be loaded from wafer containers (e.g., cassettes) to the loading station 170 using the wafer transfer robot 180. The wafer transfer robot 180 is further configured to grab the batch of wafers 10 loaded on the loading station 170 and slide along a slide rail 190 to transfer the wafers 10 to different apparatuses (e.g., the processing apparatuses 110a, 110b, and 110c). The wafer transfer robot 180 may load the wafers 10 on a batch wafer carriers 112a, 112b, and 112c of the processing apparatuses 110a, 110b, and 110c. The batch wafer carrier 112a, 112b, or 112c with the wafers 10 is then immersed into the corresponding chamber of the processing apparatus 110a, 110b, or 110c.

When the process is complete, the batch wafer carrier 112a, 112b, or 112c with the wafers 10 is supposed to be lifted from the corresponding chamber, and/or the wafer transfer robot 180 is supposed to grab the batch of wafers 10 from the batch wafer carrier 112a, 112b, and 112c. In some embodiments, however, the batch wafer carrier 112a, 112b, and 112c or the wafer transfer robot 180 may not work, the wafers 10 may be over-immersed in the processing solutions, and the structures on the wafers 10 may be damaged. Therefore, some embodiments of the present disclosure provide methods for transferring the batch of wafers 10 when the batch wafer carrier 112a, 112b, and 112c or the wafer transfer robot 180 do not work.

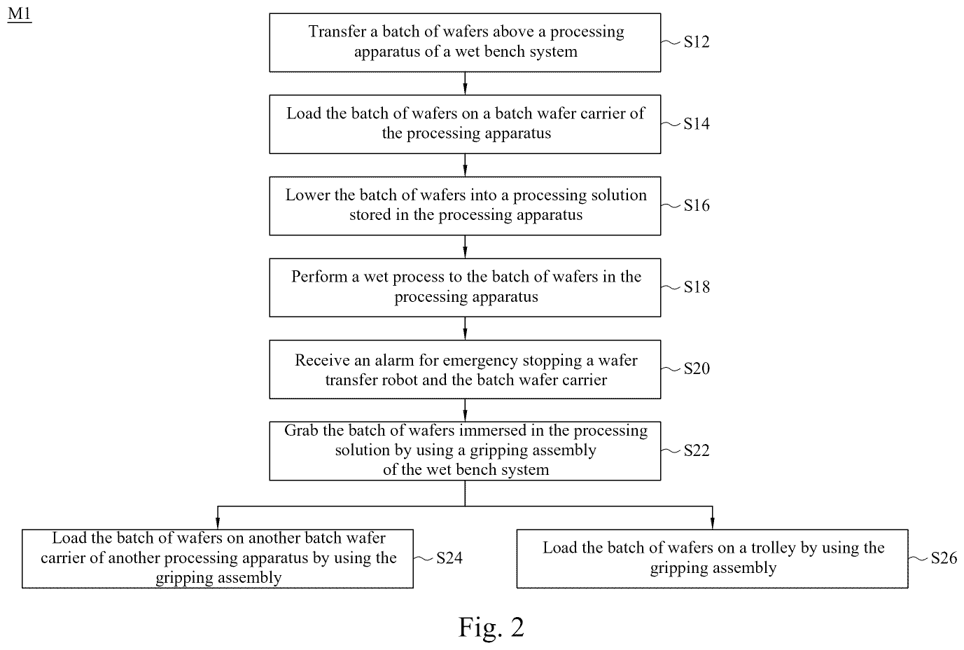

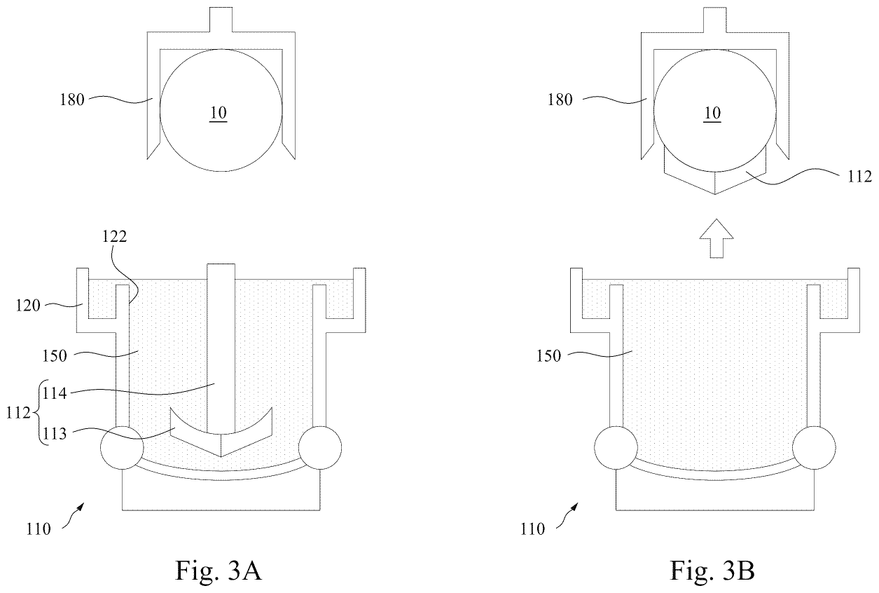

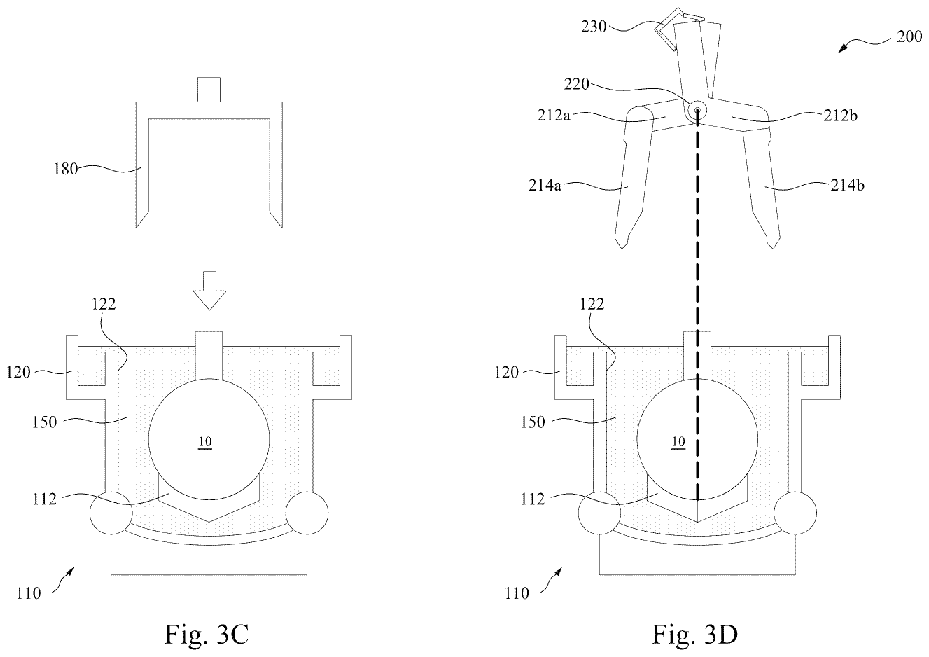

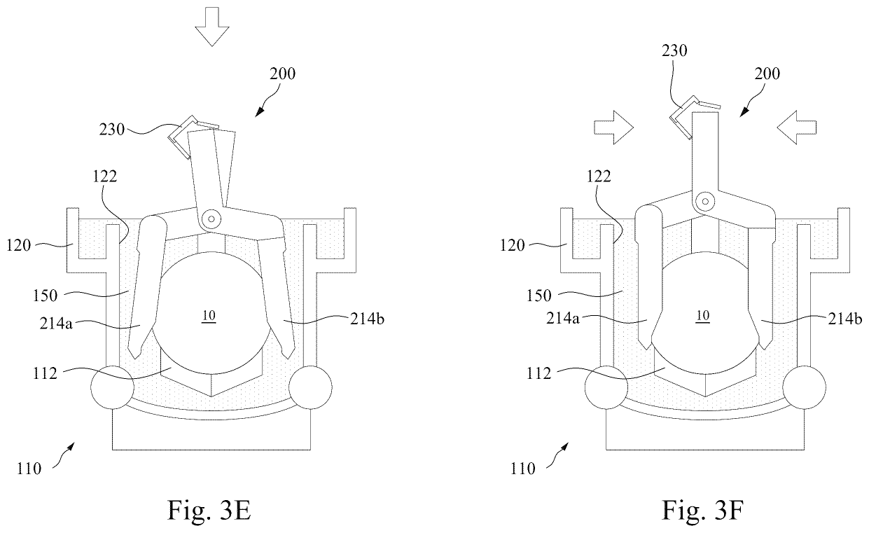

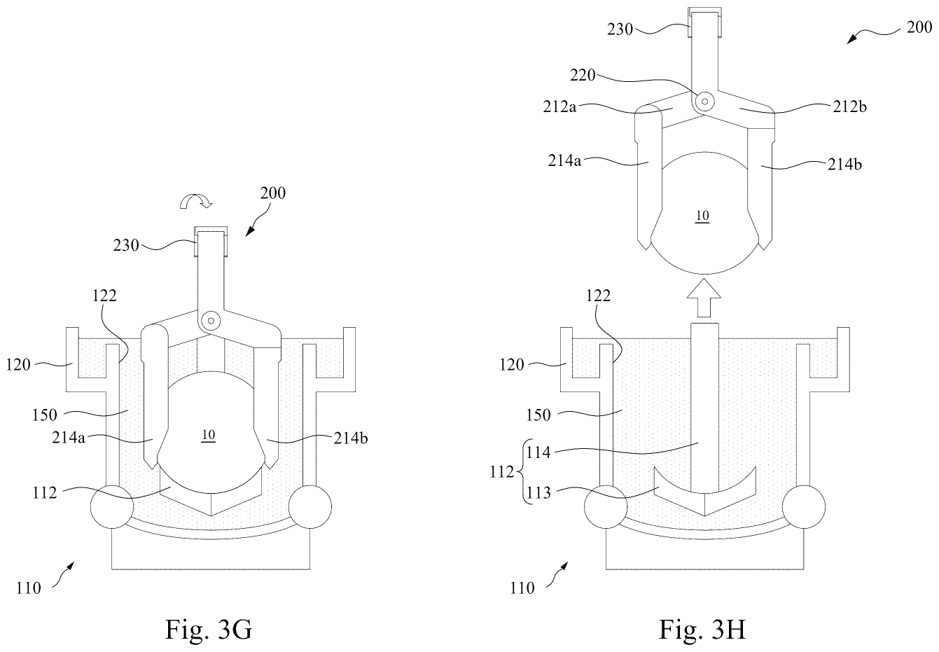

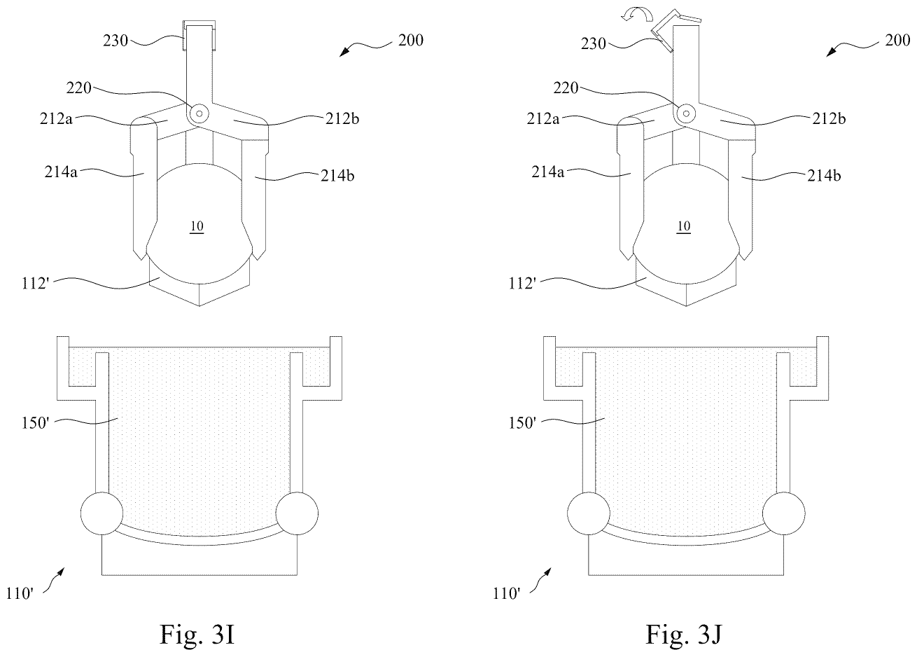

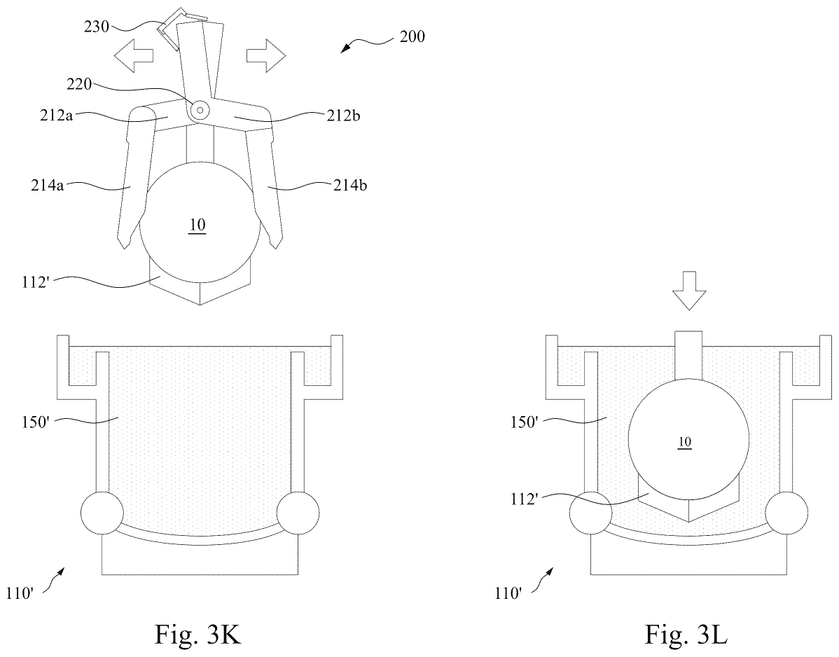

The wet bench system 100 further includes a gripping assembly 200 and a trolley 300 for transferring the batch of wafers 10 when the batch wafer carrier 112a, 112b, and 112c or the wafer transfer robot 180 do not work, and the details for using the gripping assembly 200 and the trolley 300 are as follows. FIG. 2 is a flowchart illustrating a method M1 for processing a batch of wafers 10 in the wet bench system 100 in accordance with some embodiments. Various operations of the method M1 are discussed in association with at least FIGS. 1-7F. It is noted that each of the methods presented below is merely an example, and not intended to limit the present disclosure beyond what is explicitly recited in the claims. Additional operations may be provided before, during, and after each of the methods. Some operations described may be replaced, eliminated, or moved around for additional embodiments of the transport methods. Additionally, for clarity and ease of explanation, some elements of the figures have been simplified. FIGS. 3A-3L are partial views of the wet bench system 100 during various stages of processing the batch of wafers 10 according to the method M1.

The operation S12 of the method M1 includes transferring a batch of wafers above a processing apparatus of a wet bench system. Reference is made to FIGS. 1 and 3A. In some embodiments, the wafer transfer robot 180 may reach to a position above the loading station 170 and grab the batch of wafers 10 loaded in the loading station 170. The wafer transfer robot 180 then slides to a position above the processing apparatus 110 and stops. The processing apparatus 110 in FIG. 3A may be the processing apparatus 110a, 110b, or 110c in FIG. 1. The processing apparatus 110 includes a housing 120 defining a processing chamber 122. The processing apparatus 110 is configured to retain a processing solution 150 within the processing chamber 122, in which the batch of wafers 10 may be immersed for a desired processing, such as etching, cleaning, or drying.

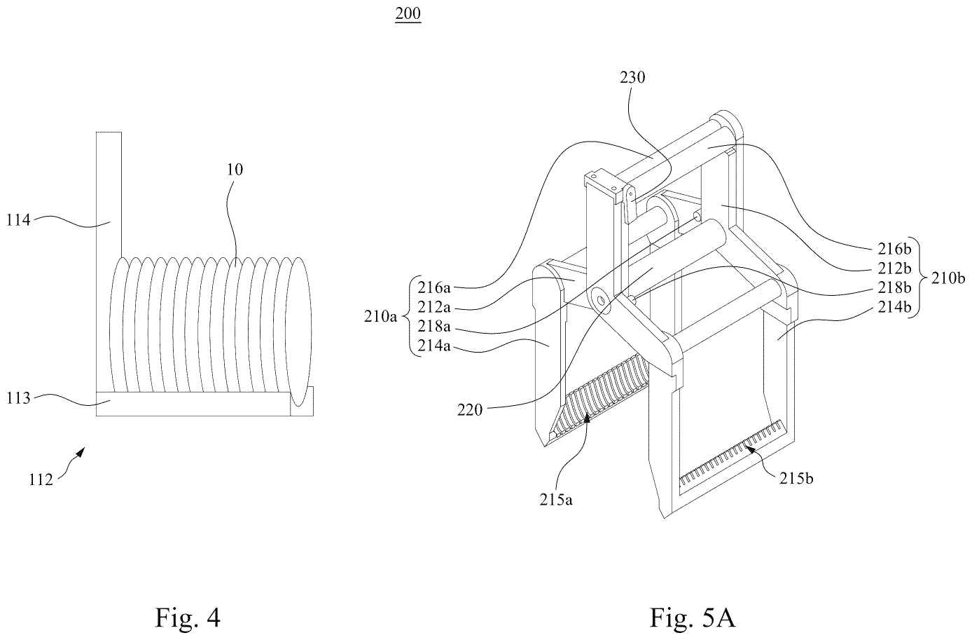

The operation S14 of the method M1 includes loading the batch of wafers on a batch wafer carrier of the processing apparatus. FIG. 4 is a schematic view of a batch of wafers 10 disposed in the batch wafer carrier 112 according to some embodiments. The batch wafer carrier 112 in FIGS. 3A-3H and 4 may be the batch wafer carrier 112a, 112b, or 112c in FIG. 1. As shown in FIGS. 3A and 4, the batch wafer carrier 112 may include a frame 113 to support the batch of wafers 10 in a parallel manner with gaps between neighboring wafers 10. The batch wafer carrier 112 may include a handle 114 extends upwards to move the frame 113 in and out of the processing apparatus 110.

In FIGS. 3A and 3B, the batch wafer carrier 112 moves upwards from the processing chamber 122 of the processing apparatus 110 and is stopped above the processing chamber 122 and beneath the batch of wafers 10 grabbed by the wafer transfer robot 180. The wafer transfer robot 180 then unloads the wafers 10 onto the frame 113 of the batch wafer carrier 112.

The operation S16 of the method M1 includes lowering the batch of wafers into a processing solution stored in the processing apparatus. As shown in FIG. 3C, the batch wafer carrier 112 with the batch of wafers 10 then move downwards and immersed in the processing solution 150 stored in the processing apparatus 110. The processing solution 150 may be various chemicals to achieve various wet bench applications. For example, the processing solution 150 used in the processing apparatus 110b in FIG. 1 (e.g., an acid tank) may be phosphoric acid (H₃PO₄), buffered hydrofluoric acid (BHF), peroxymonosulfuric acid (H₂SO₅, or Caro), a high concentration hydrofluoric acid (HF), a high concentration SC1 (such as SC1 including 5 parts of deionized water, 1 part of NH₄OH, and 1 part of H₂O₂), a high concentration SC2 (such as SC1 solution including 6 parts deionized water, 1 part of HCl, and 1 part of H₂O₂), or other suitable wet processing agents.

In some other embodiments, the processing solution 150 used in the processing apparatus 110a in FIG. 1 (e.g., a cleaning tank) may be a cleaning liquid. The wafers 10 may be immersed within the processing solution 150 in the processing apparatus 110a for a quick dump rinse (QDR) or a quick etch rinse (QER) process. The processing solution 150 may be a deionized water, or a dilute solution, such as a low concentration SC1, a low concentration SC2, a diluted HF, or other suitable wet processing agents. In still some other embodiments, the processing solution 150 used in the processing apparatus 110c in FIG. 1 (e.g., a cleaning tank) may include isopropyl alcohol (IPA).

The operation S18 of the method M1 includes performing a wet process to the batch of wafers in the processing apparatus. In some embodiments, the wet process is a wet etching process, and the processing apparatus 110 is a wet etching apparatus (e.g., the processing apparatus 110b in FIG. 1). The processing apparatus 110b in FIG. 1 may include a pump 134 positioned in a circulate conduit 136 to circulate the processing solution 150 (see FIG. 3C) in the processing chamber 122 (see FIG. 3C). The processing apparatus 110b may further include a filter 138 positioned to remove impurities from the processing solution 150. A heater 139 may be disposed in the circulate conduit 136 to heat the processing solution 150 flowing through the circulate conduit 136. The wafers 10 are immersed in the processing solution 150 for a period of time to achieve desired processing results. For example, the processing solution 150 in the processing apparatus 110b is configured to process a wet etching process to the wafers 10.

In some embodiments, the wet process is a wet cleaning process, and the processing apparatus 110 is a wet cleaning apparatus (e.g., the processing apparatus 110a in FIG. 1). The processing apparatus 110a in FIG. 1 may include a chemical manifold 142 configured to selective supply one or more processing chemicals to the processing chamber. The chemical manifold 142 may be connected to a chemical source 144 and a deionized water source 146 to generate the processing solutions including various chemicals at various concentrations. In some embodiments, the processing apparatus 110a further includes a heater 148. In some embodiments, the heater 148 may be connected to the deionized water source 146 to supply a flow of heated deionized water to the processing chamber. In some other embodiments, the heater 148 may be disposed between the chemical manifold 142 and the processing chamber to heat any solution supplied to the processing apparatus 110a. In some embodiments, the wet process is a dry process, and the processing apparatus 110 is a dryer (e.g., the processing apparatus 110c in FIG. 1).

The operation S20 of the method M1 includes receiving an alarm for emergency stopping the wafer transfer robot and the batch wafer carrier. As shown in FIG. 3C, after the wet process is complete, the batch wafer carrier 112 is supposed to lift up the batch of wafers 10, and the wafer transfer robot 180 is supposed to grab the batch of wafers 10 from the batch wafer carrier 112. However, in some scenarios, the batch wafer carrier 112 and/or the wafer transfer robot 180 may meet electrical failure and the machine conveying system of the wet bench system 100 may raise an alarm for emergency stopping the wafer transfer robot 180 and the batch wafer carrier 112. Under these situations, the wafers 10 may be immersed in the processing solution 150 for a long time, such that the structures formed over the wafers 10 may be damaged by the processing solution 150. Therefore, the gripping assembly 200 can be provided to clamp the batch of wafers 10 and lift the wafers 10 out of the processing solution 150 effectively. Since the gripping assembly 200 is electrically isolated from the wafer transfer robot 180 and the batch wafer carrier 112, the gripping assembly 200 still works when the wafer transfer robot 180 and/or the batch wafer carrier 112 is out of work.

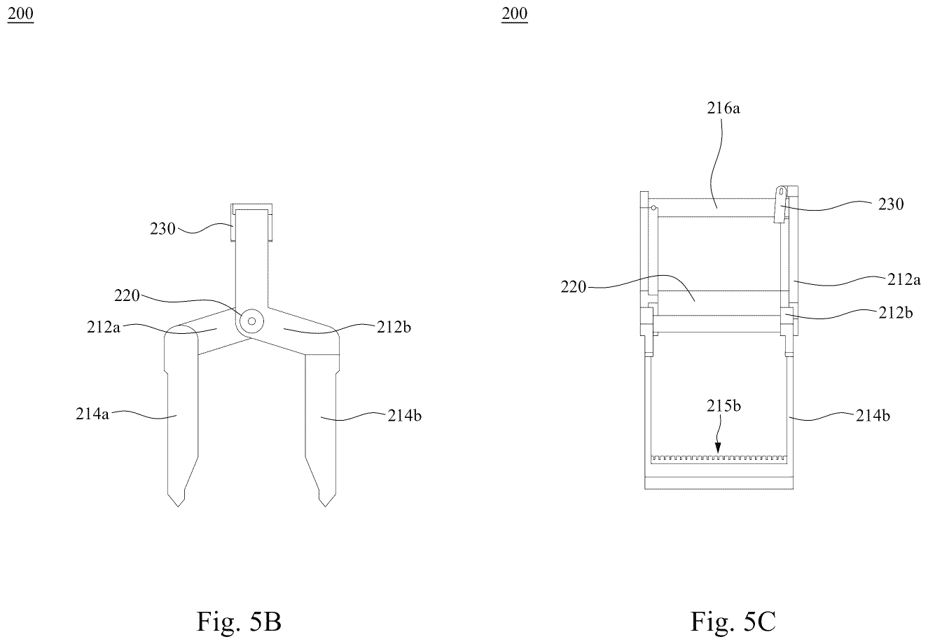

The operation S22 of the method M1 includes grabbing the batch of wafers immersed in the processing solution by using a gripping assembly of the wet bench system. FIG. 5A is a perspective view of the gripping assembly 200 in a latched state in accordance with some embodiments of the present disclosure, FIG. 5B is a front view of the gripping assembly 200 in FIG. 5A, and FIG. 5C is a side view of the gripping assembly 200 in FIG. 5A. The gripping assembly 200 includes a pair of gripping arms 210a and 210b assembled by or coupled to a rotating shaft 220. Specifically, the gripping arm 210a includes a bracket 212a, an arm portion 214a, and a handle 216a. The arm portion 214a is connected to the bracket 212a and extends from the bracket 212a. The handle 216a is connected to the bracket 212a. Similarly, the gripping arm 210b includes a bracket 212b, an arm portion 214b, and a handle 216b. The arm portion 214b is connected to the bracket 212b and extends from the bracket 212b. The handle 216b is connected to the bracket 212b. The rotating shaft 220 is coupled to the bracket 212a and 212b, such that the gripping arms 210a and 210b are coupled to each other. The handle 216a and the arm portion 214a are on opposite sides of the bracket 212a (and the rotating shaft 220), and the handle 216b and the arm portion 214b are on opposite sides of the bracket 212b (and the rotating shaft 220).

The gripping assembly 200 further includes a locking fastener 230 connected to the bracket 212a. After the handles 216a and 216b are put together (or merged) as shown in FIG. 5A, the locking fastener 230 can be used to lock the handles 216a and 216b. Therefore, the arm portions 214a and 214b are not spaced apart from each other and the gripping assembly 200 is in a latched state. On the contrary, when the locking fastener 230 is unlocked, the arm portions 214a and 214b can be separated from each other, and the gripping assembly 200 is in an unlatched (or open) state.

The arm portion 214a has a plurality of slots 215a on its bottom, and the arm portion 214b has a lot of slots 215b on its bottom. Therefore, when the gripping assembly 200 is in the latched state, the arm portions 214a and 214b together hold and clamp the batch of wafers 10 on the batch wafer carrier 112, and the gripping assembly 200 can grab the wafers 10 from the batch wafer carrier 112.

In some embodiments, as shown in FIGS. 1 and 3C, when the batch wafer carrier 112 and/or the wafer transfer robot 180 is/are not working, the machine conveying system (including the batch wafer carrier 112 and the wafer transfer robot 180) of the wet bench system 100 is alarmed, and the whole machine conveying system stops. In FIG. 3D, an operators may bring the gripping assembly 200 to the processing apparatus 110 and unlatch the gripping assembly 200. That is, the operator may separate the handles 216a and 216b from each other. Alternatively, the gripping assembly 200 is provided in an unlatched state. The operator may grab the handles 216a and 216b and put the gripping assembly 200 above the processing solution 150 and the batch of wafers 10. In some embodiments, the operator may align a position of the rotating shaft 220 of the gripping assembly 200 with a position of the batch of wafers 10 (and the batch wafer carrier 112) from top, avoiding the gripping assembly 200 collide the wafers 10 when the gripping assembly 200 put into the processing solution 150.

The unlatched gripping assembly 200 is then immersed in the processing solution 150. As shown in FIG. 3E, after the alignment operation, the operator may grab the handles 216a and 216b (see FIG. 5A) and move the gripping assembly 200 into the processing chamber 122 and in the processing solution 150. The arm portions 214a and 214b of the gripping assembly 200 are then on opposite sides of the wafers 10.

Subsequently, the batch of wafers 10 in the processing solution 150 are clamped by using the gripping assembly 200. As shown in FIGS. 3F and 5A, the operator may put the handles 216a and 216b together, such that the arm portions 214a and 214b together clamp the wafers 10. In some embodiments, the gripping arms 210a and 210b of the gripping assembly 200 further includes stoppers 218a and 218b (see FIG. 5A), respectively. The stoppers 218a and 218b are on inner sidewalls of the brackets 212a and 212b, respectively. When the handles 216a and 216b are put together, the bracket 212a touches the stopper 218b, and the bracket 212b touches the stopper 218a, such that the gripping arms 210a and 210b do not clamp the wafers 10 too tight.

It is noted that, in some embodiments, the pitch of the slots 215a and 215b of the gripping assembly 200 is the same or substantially the same as the pitch of grooves of the batch wafer carrier 112 which the wafers 10 are placed in. With this configuration, when the gripping assembly 200 clamps the wafers 10, the position of the slots 215a and 215b of the gripping assembly 200 can fit the positions of the wafers 10, and the arm portions 214a and 214b of the gripping assembly 200 do not collide with the wafers 10 and clamp the wafer 10 accurately. After the handles 216a and 216b are put together, the operator may lock the locking fastener 230 to fix the relative position between the handles 216a and 216b. Therefore, the gripping assembly 200 is in the latched state as shown in FIG. 3G.

The operator then pulls the latched gripping assembly 200 with the batch of wafers 10 out of the processing solution 150 as shown in FIG. 3H. The latched gripping assembly 200 with the batch of wafers 10 is held by the operator and is pulled to a position above the processing apparatus 110. Meanwhile, the batch wafer carrier 112 is still in the processing solution 150 and in the processing chamber 122. The operator may then repair or fix the issues of the batch wafer carrier 112 and/or the wafer transfer robot 180 without concerning the over-immersion issues of the wafers 10.

Reference is made back to FIG. 2. In some embodiments, the operation S22 then goes to operation S24, which includes loading the batch of wafers on another batch wafer carrier of another processing apparatus by using the gripping assembly. As shown in FIG. 3I, the wafers 10 with the gripping assembly 200 are loaded on a batch wafer carrier 112′ of a processing apparatus 110′. As mentioned above, since the slots 215a and 215b of the gripping assembly 200 have substantially the same pitch as the grooves of the batch wafer carrier 112 (and 112′), the positions of the wafers 10 substantially remain the same when the wafers 10 are loaded on the batch wafer carrier 112′. In some embodiments, the processing apparatus 110′ is the processing apparatus 110a, 110b, or 110c in FIG. 1, and the batch wafer carrier 112′ is the batch wafer carrier 112a, 112b, or 112c in FIG. 1.

For example, when the processing apparatus 110 in FIGS. 3A-3H is the processing apparatus 110b in FIG. 1, the operator may grab the gripping assembly 200 in FIG. 3H and transfer the wafers 10 to the processing apparatus 110a. After the batch wafer carrier 112a of the processing apparatus 110a is lifted above the processing apparatus 110a, the operator may put the wafers 10 with the gripping assembly 200 on the batch wafer carrier 112a. Therefore, the wafers 10 will undergo a wet cleaning process in the processing apparatus 110a. Alternatively, the processing apparatus 110 in FIGS. 3A-3H is the processing apparatus 110a in FIG. 1, the operator may hold the gripping assembly 200 in FIG. 3H and transfer the wafers 10 to the processing apparatus 110c. After the batch wafer carrier 112a of the processing apparatus 110c is lifted above the processing apparatus 110c, the operator may put the wafers 10 with the gripping assembly 200 on the batch wafer carrier 112a. Therefore, the wafers 10 will undergo a drying process in the processing apparatus 110c or a wet etching process in the processing apparatus 110b.

After the wafers 10 are loaded on the batch wafer carrier 112', the operator may unlock the locking fastener 230 as shown in FIG. 3J. Next, the operator may separate the handles 216a and 216b (see FIG. 5A) of the gripping assembly 200 as shown in FIG. 3K. The wafers 10 are then detached from the gripping assembly 200, and the gripping assembly 200 can be removed from the processing apparatus 110′. Subsequently, as shown in FIG. 3L, the batch wafer carrier 112′ with the batch of wafers 10 then move downwards and immersed in the processing solution 150′ stored in the processing apparatus 110′ to undergo another wet process in the processing apparatus 110′.

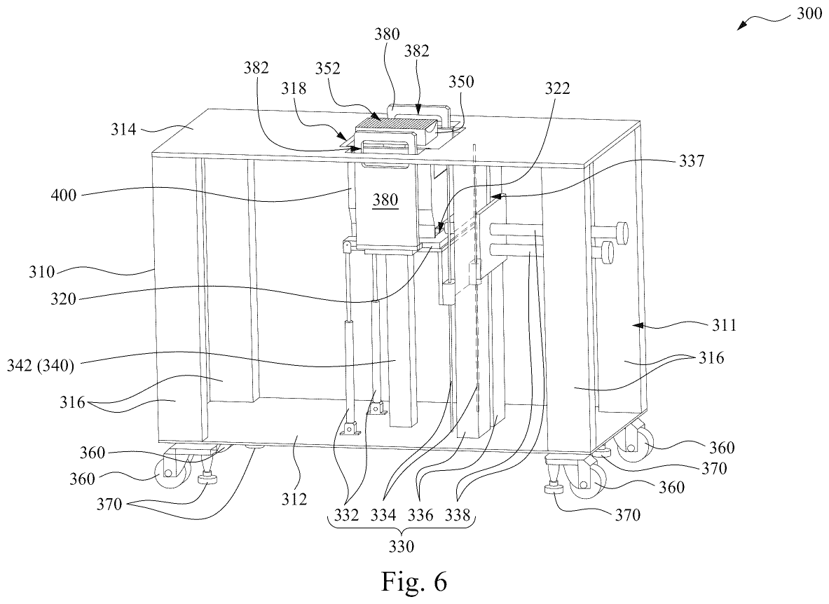

Reference is made back to FIG. 2. In some other embodiments, the operation S22 then goes to operation S26, which includes loading the batch of wafers on a trolley of the wet bench system by using the gripping assembly. In FIG. 1, the trolley 300 is movable among the processing apparatuses 110a-110c. FIG. 6 is a perspective view of a trolley 300 and a wafer container 400 in accordance with some embodiments of the present disclosure. The trolley 300 of the wet bench system 100 includes a frame 310, a base 320, a lifting assembly 330, a bracket assembly 340, a wafer supporting plate 350, and a plurality of wheels 360. The frame 310 includes a bottom plate 312, a top plate 314, and a plurality of pillars 316 interconnecting the bottom plate 312 and the top plate 314. The top plate 314 has an opening 318 therein.

The base 320 is in an accommodating area 311 confined by the frame 310 and under the opening 318 of the top plate 314. The base 320 may be substantially parallel to the top plate 314 and/or the bottom plate 312 of the frame 310. The base 320 has an opening 322 therein. The wafer container 400 may be placed on the base 320 as shown in FIG. 6.

The lifting assembly 330 includes a plurality of telescopic poles 332, a plurality of slide rails 334, fixing elements 336, and handles 338. The telescopic poles 332 are connected to a side of the base 320, and the slide rails 334 are connected to another side of the base 320. The fixing elements 336 are fixed on the top plate 314 and the bottom plate 312 of the frame 310. The handles 338 pass through a slit 337 between the fixing elements 336 and connected to the base 320. When the handles 338 are moved upwards and/or downwards, the base 320 can be moved upwards and/or downwards, correspondingly. That is, the base 320 is movable relative to the top plate 314 and the bottom plate 312 of the frame 310.

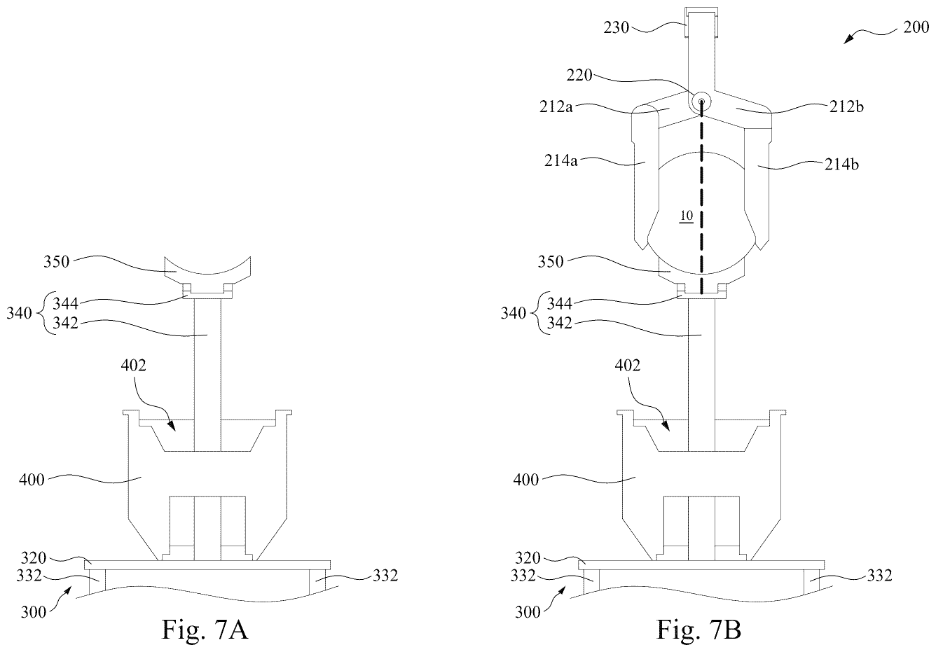

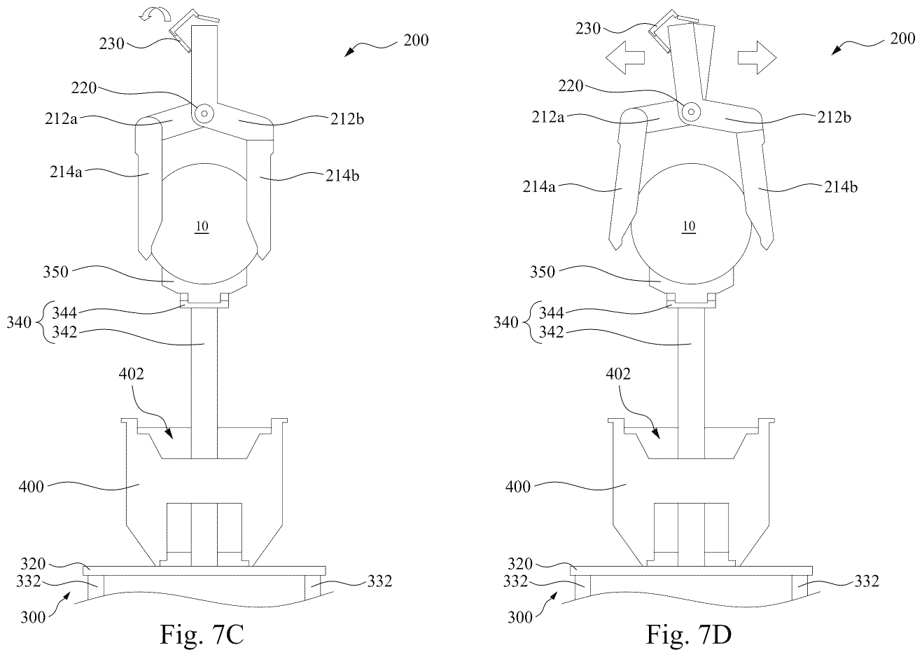

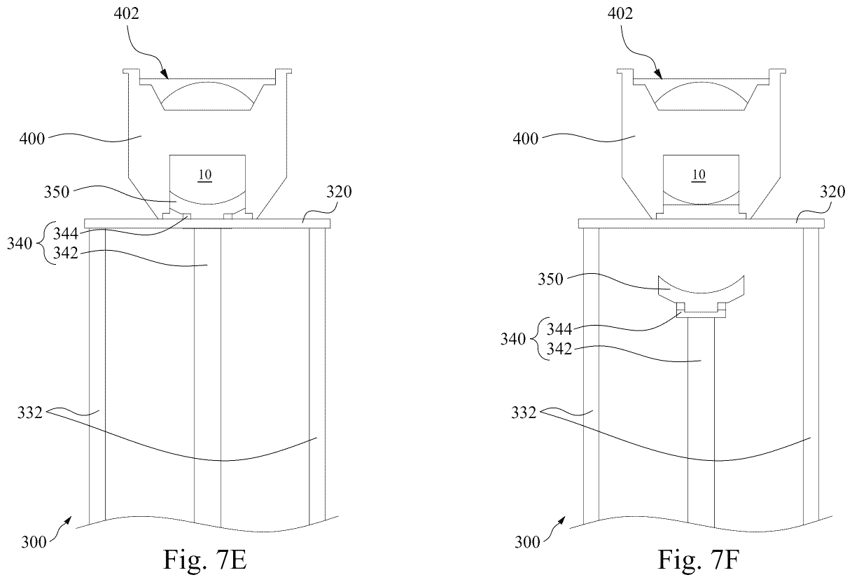

The bracket assembly 340 includes a shaft 342 and a supporting bracket 344 (see FIGS. 7A-7F) over the shaft 342. The shaft 342 protrudes from the bottom plate 312 of the frame 310 and passes through the opening 322 of the base 320, and the supporting bracket 344 is fixed on the top of the shaft 342. The wafer supporting plate 350 is placed on the supporting bracket 344 of the bracket assembly 340. In some embodiments, as shown in FIG. 6, the wafer supporting plate 350 is placed in the opening 318 of the top plate 314. Further, the wafer supporting plate 350 has a plurality of slots 352 parallel to each other and has a pitch substantially the same as a pitch of the slots 215a and 215b (see FIG. 5A) of the gripping assembly 200.

The wheels 360 are under the bottom plate 312 of the frame 310. In some embodiments, the trolley 300 further includes a plurality of leveling pads 370 adjacent to the wheels 360, respectively. The leveling pads 370 are configured to fix the position of the trolley 300 when the trolley 300 is moved to a desired position.

In some embodiments, the trolley 300 further includes a pair of holding plates 380 on opposite sides of the base 320. The holding plates 380 each has an opening 382 therein. An operator may optionally hold the holding plates 380 and lift the base 320 with the wafer container 400 upwards or downwards. Therefore, the base 320 with the wafer container 400 may move relative to the wafer supporting plate 350.

FIGS. 7A-7F are partial views of the trolley 300 during various stages of loading the wafers 10 in the wafer container 400 according to the operation S26 of the method M1. In FIG. 7A, the trolley 300 is provided. In some embodiments, when the batch of wafers 10 in FIG. 3H is scheduled to move to other places, the wafers 10 can be placed in the wafer container 400 and then the wafer container 400 with the wafers 10 can be transferred in a safety way. The trolley 300 may be moved to a place near the processing apparatus 110′ (see FIG. 3H). The wafer container 400 is placed on the base 320 of the trolley 300. Specifically, the wafer container 400 has an accommodating area 402 for accommodating the wafers 10. Further, the accommodating area 402 is open on both the top and bottom of the wafer container 400. Therefore, when the wafer container 400 is placed on the base 320 of the trolley 300, the shaft 342 of the bracket assembly 340 passes through the accommodating area 402 of the wafer container 400. It is noted that the holding plates 380, the top plate 314, and some other elements of the trolley 300 are omitted in FIGS. 7A-7F for clarity.

Subsequently, as shown in FIG. 7B, the wafers 10 clamped by the gripping assembly 200 in FIG. 3H is transferred and placed on the wafer supporting plate 350. As mentioned above, since the slots 352 of the wafer supporting plate 350 has a pitch substantially the same as a pitch of the slots 215a and 215b (see FIG. 5A) of the gripping assembly 200, the positions of the wafers 10 substantially remain the same when the wafers 10 are loaded on the wafer supporting plate 350. Further, prior to place the wafers 10 on the wafer supporting plate 350, the operator may align the shaft 220 of the gripping assembly 200 with a central axis of the wafer supporting plate 350 to avoid the wafers 10 collide with the wafer supporting plate 350 when the wafers 10 are put on the wafer supporting plate 350.

The operator then unlocks the gripping assembly 200 and loads the wafers 10 on the wafer supporting plate 350. Similar to FIGS. 3I-3K, the operator may unlock the locking fastener 230 as shown in FIG. 7C. Next, the operator may separate the handles 216a and 216b (see FIG. 5A) of the gripping assembly 200 as shown in FIG. 7D. The wafers 10 are then detached from the gripping assembly 200, and the gripping assembly 200 can be removed from the trolley 300.

In FIGS. 6 and 7E, the base 320 of the trolley 300 is lifted up from the bottom plate 312. The lifting assembly 330 is configured to lift the base 320 from the accommodating area 311 of the frame 310 in a vertical direction. As the base 320 is lifted, the wafer container 400 placed on the base 320 is also lifted until the wafer container 400 supports the wafers 10.

As the wafers 10 are held by the wafer container 400 instead of by the wafer supporting plate 350, the wafer supporting plate 350 may be optionally lowered relative to the base 320 as shown in FIG. 7F, such that the wafers 10 are detached from the wafer supporting plate 350 and are accommodated in the accommodating area 402 of the wafer container 400. Thereafter, the wafer container 400 with the wafers 10 can be transferred to a desired position to implement the next fabrication processes.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the gripping assembly can be applied to wet processes to save the wafers immersed in the processing solution in time, thereby avoiding a large amount of product scrapping and reducing the workload of operators. Further, it is convenience to grab the gripping assembly with the wafers to the desired positions to implement the following fabrication processes. In addition, the locking fastener of the gripping assembly ensures the safety and reliability of transferring the wafers, preventing the wafers dropping from the gripping assembly. The pitch of the slots of the gripping assembly is substantially the same as the pitch of the grooves of the batch wafer carrier, decreasing the collision possibility among the wafers when the gripping assembly clamps the wafers.

According to some embodiments, a method includes grabbing a gripping assembly and moving the gripping assembly into a processing solution. The batch of wafers in the processing solution is clamped by using the gripping assembly. The gripping assembly is locked. The gripping assembly with the batch of wafers is pulled out of the processing solution.

According to some embodiments, the method includes transferring a batch of wafers by using a wafer transfer robot of a wet bench system to a position above a first processing apparatus of the wet bench system. The batch of wafers are loaded, by using the wafer transfer robot, to a first batch wafer carrier of the first processing apparatus. The first batch wafer carrier with the batch of wafers is lowered into a processing solution stored in a processing chamber of the first processing apparatus. The batch of wafers immersed in the processing solution are clamped by using a gripping assembly. The gripping assembly with the batch of wafers is grabbed out of the processing solution.

According to some embodiments, a wet bench system includes a first processing apparatus, a wafer transfer robot, and a gripping assembly. The first processing apparatus includes a housing defining a processing chamber and a batch wafer carrier movable in the housing and including a frame configured to support a wafer. The wafer transfer robot is configured to transfer the wafer onto the batch wafer carrier. The gripping assembly is configured to clamp the wafer from the batch wafer carrier. The gripping assembly includes a pair of gripping arms coupled by a rotating shaft, the gripping arms each has a handle and an arm portion on opposite sides of the rotating shaft, the arm portion has a plurality of slots, and a pitch of the slots is substantially the same as a pitch of grooves of the batch wafer carrier.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
grabbing a gripping assembly and moving the gripping assembly into a processing solution;
clamping a batch of wafers in the processing solution by using the gripping assembly;
locking the gripping assembly; and
pulling the gripping assembly with the batch of wafers out of the processing solution.

2. The method of claim 1, wherein the gripping assembly comprises:
a pair of gripping arms, each of the gripping arms comprising:
a handle;
an arm portion; and
a bracket interconnecting the handle and the arm portion; and
a rotating shaft coupled to the brackets of the pair of gripping arms.

3. The method of claim 2, wherein providing the gripping assembly comprises:
separating the handles of the gripping arms from each other.

4. The method of claim 2, wherein clamping the batch of wafers comprises:
putting the handles of the gripping arms together.

5. The method of claim 2, further comprising:
aligning a position of the rotating shaft with a position of the batch of wafers prior to moving the gripping assembly into the processing solution.

6. The method of claim 1, further comprising:
grabbing the gripping assembly with the batch of wafers to a batch wafer carrier of a processing apparatus.

7. The method of claim 6, further comprising:
unlocking a locking fastener of the gripping assembly after grabbing the gripping assembly with the batch of wafers to the batch wafer carrier; and
detaching the batch of wafers from the gripping assembly.

8. The method of claim 1, further comprising:
grabbing the gripping assembly with the batch of wafers to a wafer supporting plate of a trolley; and
loading the batch of wafers on the wafer supporting plate to a wafer container.

9. A method comprising:
transferring a batch of wafers by using a wafer transfer robot of a wet bench system to a position above a first processing apparatus of the wet bench system;
loading the batch of wafers, by using the wafer transfer robot, to a first batch wafer carrier of the first processing apparatus;
lowering the first batch wafer carrier with the batch of wafers into a processing solution stored in a processing chamber of the first processing apparatus;
clamping the batch of wafers immersed in the processing solution by using a gripping assembly; and
grabbing the gripping assembly with the batch of wafers out of the processing solution.

10. The method of claim 9, wherein after grabbing the gripping assembly with the batch of wafers out of the processing solution, the first batch wafer carrier remains in the processing solution.

11. The method of claim 9, wherein the gripping assembly is electrically isolated from the wafer transfer robot.

12. The method of claim 9, further comprising:
repairing the wafer transfer robot after grabbing the gripping assembly with the batch of wafers out of the processing solution.

13. The method of claim 9, further comprising:
transferring the gripping assembly with the batch of wafers on a wafer supporting plate of a trolley.

14. The method of claim 13, wherein the trolley comprises:
a frame;
a base in the frame and having an opening therein;
a bracket assembly connected to the frame and passing through the base; and
the wafer supporting plate on the bracket assembly.

15. The method of claim 14, further comprising:
placing a wafer container on the base of the trolley prior to transferring the gripping assembly with the batch of wafers on the wafer supporting plate of the trolley, wherein the bracket assembly further passes through the wafer container.

16. The method of claim 15, further comprising:
after transferring the gripping assembly with the batch of wafers on the wafer supporting plate, lifting the base with the wafer container up to the wafer supporting plate until the wafer container supports the batch of wafer.

17. The method of claim 16, further comprising:
after the wafer container supports the batch of wafer, lowering the wafer supporting plate relative to the base.

18. The method of claim 9, further comprising:
transferring the gripping assembly with the batch of wafers to a position above a second processing apparatus of the wet bench system; and
putting the gripping assembly with the batch of wafers on a second batch wafer carrier of the second processing apparatus.

19. A wet bench system comprising:
a first processing apparatus comprising:
a housing defining a processing chamber; and
a batch wafer carrier movable in the housing and comprising a frame configured to support a wafer;
a wafer transfer robot configured to transfer the wafer onto the batch wafer carrier; and
a gripping assembly configured to clamp the wafer from the batch wafer carrier, wherein the gripping assembly comprises a pair of gripping arms coupled by a rotating shaft, the gripping arms each has a handle and an arm portion on opposite sides of the rotating shaft, the arm portion has a plurality of slots, and a pitch of the slots is substantially the same as a pitch of grooves of the batch wafer carrier.

20. The wet bench system of claim 19, further comprising:
a second processing apparatus; and
a trolley movable between the first processing apparatus and the second processing apparatus, wherein the trolley comprises:
a frame;
a base in the frame and having an opening therein;
a bracket assembly connected to the frame and passing through the base; and
a wafer supporting plate on the bracket assembly, wherein the gripping assembly is further configured to transfer the wafer to the wafer supporting plate.
